(19) United States
(12) Patent Application Publication
(10) Pub. No.: US 2007/0121290 A1
(43) Pub. Date: May 31, 2007

(54) DETACHABLE FAN ASSEMBLY

(75) Inventors: Miao-Tzu Chou, TAIPEI (TW); Kuang-Yu Tseng, TAIPEI (TW); Chia-Yen Hsu, TAIPEI (TW)

Correspondence Address: DATAVAN INTERNATIONAL CORP., P.O. BOX 108-00403, TAIPEI, TW

(73) Assignee: DATAVAN INTERNATIONAL CORP., Jhonghe City, Taipei Hsien (TW)

(21) Appl. No.: 11/164,597

(22) Filed: Nov. 30, 2005

(51) Int. Cl. H05K 7/20

(52) U.S. Cl. 361/695

(57) ABSTRACT

A detachable fan assembly, which includes a casing, which has an opening and angled lugs at two sides of the opening, a mounting frame, which has hooked portions respectively detachably hooked on the angled lugs of the casing, a fan fastened to the mounting frame with fastening members, and a grille, which is covered on the opening of the casing to hold down the mounting frame on the angled lugs of the casing and which has a locating flange at one lateral side and a plurality of protruding retaining portions disposed at the other lateral side and respectively fastened to the casing at two sides of the opening and a finger strip for the pulling of the hand to separate the grille from the casing.

### BACKGROUND OF THE INVENTION

1. Field of the Invention

The present invention relates to a fan assembly for cooling and more particularly, to a detachable fan assembly, which is conveniently detachable to facilitate the performance of a maintenance work.

2. Description of the Related Art

Following fast development of computer technology, a variety of advanced computers have been created for different purposes and have appeared on the market. A computer has a power supply unit adapted to provide the system with the necessary working voltage. During operation of the computer, the power supply unit produces heat, which may affect the performance of other component parts inside the computer. In order to dissipate heat from the power supply unit, a fan may be used. FIG. 6 shows a fan B mounted inside the casing of a power supply unit A. In case, the fan B failed or is unable to function well due to the effect of a thick layer of dust, the user cannot immediately replace the fan B. In this case, the user must remove the power supply unit A from the computer, and then detach the casing of the power supply unit A, and then replace or repair the fan B. This arrangement complicates the maintenance of the fan B.

### SUMMARY OF THE INVENTION

The present invention has been accomplished under the circumstances in view. It is the main object of the present invention to provide a fan assembly, which is detachable to facilitate the performance of a maintenance work. To achieve this and other objects of the present invention, the detachable fan assembly comprises detachable fan assembly comprises a casing and a fan set detachably mounted inside the casing. The fan set comprises a fan, a mounting frame adapted to hold the fan inside the casing, and a grille detachably fastened to an opening at one side of the casing to hold down the mounting frame in the casing. The mounting frame has a plurality of hooked portions respectively fastened to respective angled lugs at the casing. The grille has a locating flange and a plurality of protruding retaining portions for fastening to the casing, and a finger strip adapted for the pulling of the hand to separate the grille from the casing.

### BRIEF DESCRIPTION OF THE DRAWINGS

FIG. 1 is an elevational view of a detachable fan assembly according to the present invention.

FIG. 2 is an exploded view of the detachable fan assembly according to the present invention.

FIG. 3 is a schematic sectional side view of the present invention showing the relationship between the parts before installation.

FIG. 4 is a schematic sectional assembly view of the detachable fan assembly according to the present invention (I).

FIG. 5 is a schematic sectional assembly view of the detachable fan assembly according to the present invention (II).

FIG. 6 is an elevational view of a conventional fan assembly.

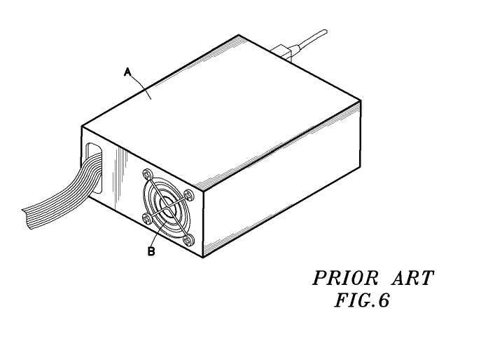

### DETAILED DESCRIPTION OF THE PREFERRED EMBODIMENT

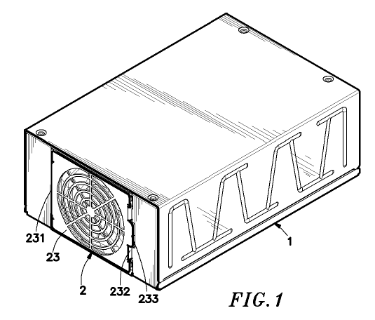

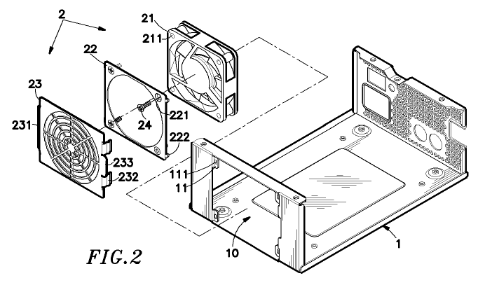

Referring to FIGS. 1 and 2, a detachable fan assembly in accordance with the present invention is shown comprised of a casing 1 and a fan set 2.

The casing 1 has an opening 10 at one side, and a plurality of angled lugs 11 suspending at two opposite lateral sides of the opening 10 and projecting toward the inside of the casing 1. The angled lugs 11 each have a retaining hole 111.

The fan set 2 comprises a fan 21, a mounting frame 22, and a grille 23. The fan 21 has a plurality of mounting holes 211. The mounting frame 22 has a plurality of mounting holes 221 respectively fastened to the mounting holes 211 of the fan 21 with fastening members 24, and a plurality of hooked portions 222 symmetrically disposed at two opposite lateral sides. The grille 23 has a locating flange 231 disposed at one lateral side, and a plurality of protruding retaining portions 232 and a finger strip 233 disposed at the other lateral side.

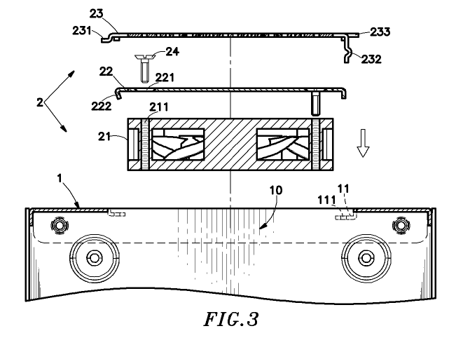

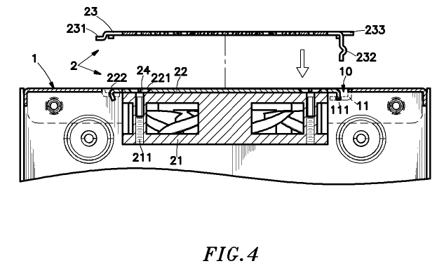

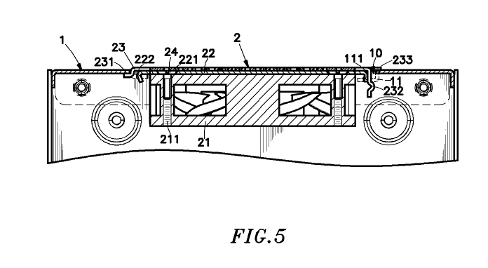

Referring to FIGS. 3-5, during installation of the fan set 2 in the casing 1, the fan 21 and the mounting frame 22 are fastened together with the fastening members 24 and then inserted into the opening 10 of the casing 1 to force the hooked portions 222 of the mounting frame 22 into engagement with the retaining holes 111 of the angled lugs 11 of the casing 1, and then the locating flange 231 of the grille 23 is inserted into one lateral side of the opening 10 of the casing 1 and the protruding retaining portions 232 of the grille 23 are forced into engagement with a part of the casing 1 at the other lateral side of the opening 10, thereby finishing the installation of the fan set 2 in the casing 1.

After a long use of the detachable fan assembly, the fan set 2 may be covered with a layer of dust. In this case, the fan set 2 must be removed from the casing 1 and well cleaned. By means of pulling the finger strip 233 outwards, the grille 23 is easily disconnected from the casing 1. After removal of the grille 23 from the casing 1, the hooked portions 222 of the mounting frame 22 are respectively disengaged from the retaining holes 111 of the angled lugs 11 of the casing 1, and then the fan 21 with the mounting frame 22 are removed from the casing 1.

Further, the aforesaid fastening members 24 can be screws, rivets, or any elements capable of securing the mounting holes 221 of the mounting frame 22 to the mounting holes 211 of the fan 21.

Further, in the aforesaid embodiment, the fan 21 and the mounting frame 22 are two independent members detachably fastened together. Alternatively, the mounting frame 22 can be formed integral with a part of the fan 21, i.e., the fan 21 can be made having hooked portions for engaging the retaining holes 111 of the angled lugs 11 of the casing 1.

As indicated above, the invention provides a detachable fan assembly, which has the following characteristics.

1. The detachable fan assembly can easily be assembled by: fastening the fan 21 and the mounting frame 22 with the fastening members 24, and then forcing the hooked portions 222 of the mounting frame 22 into engagement with the retaining holes 111 of the angled lugs 11 of the casing 1, and then forcing the locating flange 231 and protruding retaining portions 232 into engagement with a part of the casing 1 at two opposite lateral sides of the opening 10.

2. The detachable fan assembly can easily be detached for a maintenance work by pulling the finger strip 233 to disengage the grille 23 from the casing 1 for enabling the fan 21 with the mounting frame 22 to be separated from the angled lugs 11 of the casing 1.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A detachable fan assembly comprising a casing and a fan set mounted inside said casing, wherein
said casing has an opening at one side, and a plurality of lugs symmetrically disposed at two opposite lateral sides of said opening, said lugs each having a retaining hole; said fan set comprises:
a fan, said fan having a plurality of mounting holes;
a mounting frame adapted to hold said fan inside said casing, said mounting frame having a plurality of mounting holes respectively connected to said mounting holes of said fan and a plurality of hooked portions respectively fastened to said retaining holes of said lugs of said casing;
a plurality of fastening members respectively fastened to said mounting holes of said mounting frame and said mounting holes of said fan to affix said fan to said mounting frame; and
a grille covered on said opening of said casing to hold down said mounting frame on said lugs of said casing, said grille having a locating flange at one lateral side and a plurality of protruding retaining portions disposed at the other lateral side and respectively fastened to said casing at two sides of said opening, and a finger strip adapted for the pulling of the hand to separate said grille from said casing.

2. The detachable fan assembly as claimed in claim 1, wherein said lugs of said casing are angled lugs.

3. The detachable fan assembly as claimed in claim 1, wherein said fastening members are screws.

4. The detachable fan assembly as claimed in claim 1, wherein said fastening members are rivets.

5. A detachable fan assembly comprising a casing and a fan set mounted inside said casing, wherein
said casing has an opening at one side, and a plurality of angled lugs symmetrically disposed at two opposite lateral sides of said opening, said angled lugs each having a retaining hole;
said fan set comprises:
a fan, said fan having a plurality of hooked portions respectively fastened to said retaining holes of said angled lugs of said casing; and
a grille covered on said opening of said casing to hold down said fan on said angled lugs of said casing, said grille having a locating flange at one lateral side and a plurality of protruding retaining portions disposed at the other lateral side and respectively fastened to said casing at two sides of said opening, and a finger strip adapted for the pulling of the hand to separate said grille from said casing.
